(19) United States
(12) Patent Application Publication
(10) Pub. No.: US 2023/0068483 A1
(43) Pub. Date: Mar. 2, 2023

(54) MICRO LED DISPLAY DEVICE

(71) Applicant: PlayNitride Display Co., Ltd., Zhunan Township (TW)

(72) Inventors: Po-Wei CHIU, Zhunan Township (TW); Sheng-Yuan SUN, Zhunan Township (TW)

(73) Assignee: PlayNitride Display Co., Ltd., Zhunan Township (TW)

(21) Appl. No.: 17/534,844

(22) Filed: Nov. 24, 2021

(30) Foreign Application Priority Data
Aug. 31, 2021 (TW) 110132278

(51) Int. Cl. H01L 27/15; H01L 33/50; H01L 33/54

(52) U.S. Cl. CPC H01L 27/156; H01L 33/50; H01L 33/54

(57) ABSTRACT

A micro LED display device is provided. The micro LED display device includes a substrate having a display region, a plurality of micro LED structures disposed inside the display region and arranged in an array, and a plurality of light-converting structures disposed on some micro LED structures. The micro LED display device also includes a positioning frame disposed outside the display region and an isolation frame surrounding the positioning frame. The water vapor transmission rate of the isolation frame is lower than the water vapor transmission rate of the positioning frame. The micro LED display device further includes a cover plate disposed on the substrate and connected to the substrate by the positioning frame and the isolation frame.

### CROSS REFERENCE TO RELATED APPLICATIONS

This Application claims priority of Taiwan Patent Application No. 110132278, filed on Aug. 31, 2021, the entirety of which is incorporated by reference herein.

### BACKGROUND

### Technical Field

Embodiments of the present disclosure relate in general to a LED display device, and in particular they relate to a micro LED display device that includes a positioning frame and an isolation frame.

### Description of the Related Art

With the advancements being made in photoelectric technology, the size of photoelectric components is gradually becoming smaller. Compared to organic light-emitting diodes (OLED), micro light-emitting diodes (micro LED, mLED/μLED) have the advantages of higher efficiency, longer life, and relatively stable materials that are not as easily affected by the environment. Therefore, displays that use micro LEDs fabricated in arrays have gradually gained attention in the market.

Quantum dots (QDs) are semiconductor particles composed of II-VI or III-V elements, and their size is generally between a few nanometers and tens of nanometers. The light-emitting color of the quantum dot material may be adjusted by its size, structure or composition, and it has the characteristics of high luminous efficiency, long service life, and high color purity. By changing the size and chemical composition of the quantum dots, the fluorescent emission wavelength may cover the entire visible light spectrum. When the quantum dots are applied in the display field (e.g., micro LED display devices), the saturation and color gamut of colors may be improved.

However, since the quantum dots are close to the size of atoms, they are quite sensitive to environmental factors such as light, heat, water and oxygen, which increase the difficulty of the packaging process. The traditional packaging method is prone to a large degree of deviation (offset) for the micro LED display device using the quantum dots, so that the user will see serious chromatic aberration when viewing the image presented by the display device from a wider angle of view (e.g., the deviation from the normal line of the micro LED display device is more than 60 degrees).

### SUMMARY

In the embodiments of the present disclosure, the micro LED display device includes a positioning frame and an isolation frame, and the water vapor transmission rate of the isolation frame is lower than the water vapor transmission rate of the positioning frame. The positioning frame may provide more accurate alignment of the two substrates in the micro LED display device, thereby effectively improving the chromatic aberration.

Some embodiments of the present disclosure include a micro LED display device. The micro LED display device includes a substrate having a display region. The micro LED display device also includes a plurality of micro LED structures disposed inside the display region and arranged in an array. The micro LED display device further includes a plurality of light-converting structures disposed on some micro LED structures to convert wavelengths of lights emitted by the portion of the micro LED structures. Moreover, the micro LED display device includes a positioning frame disposed outside the display region. The micro LED display device also includes an isolation frame surrounding the positioning frame. The water vapor transmission rate of the isolation frame is lower than the water vapor transmission rate of the positioning frame. The micro LED display device further includes a cover plate disposed on the substrate and connected to the substrate by the positioning frame and the isolation frame.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial top view of illustrating the micro LED display device according to an embodiment of the present disclosure.

FIG. 2A is a partial cross-sectional view illustrating the micro LED display device along line A-A′ according to an embodiment of the present disclosure.

FIG. 2B is a partial cross-sectional view illustrating the micro LED display device along line A-A′ according to another embodiment of the present disclosure.

FIG. 3 is a partial top view of illustrating the micro LED display device according to an embodiment of the present disclosure.

FIG. 4 is a partial cross-sectional view illustrating the micro LED display device along line B-B′ of FIG. 3.

FIG. 5 is a partial cross-sectional view of illustrating the micro LED display device according to another embodiment of the present disclosure.

FIG. 6 is a partial cross-sectional view of illustrating the micro LED display device according to another embodiment of the present disclosure.

FIG. 7 is a partial cross-sectional view of illustrating the micro LED display device according to another embodiment of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

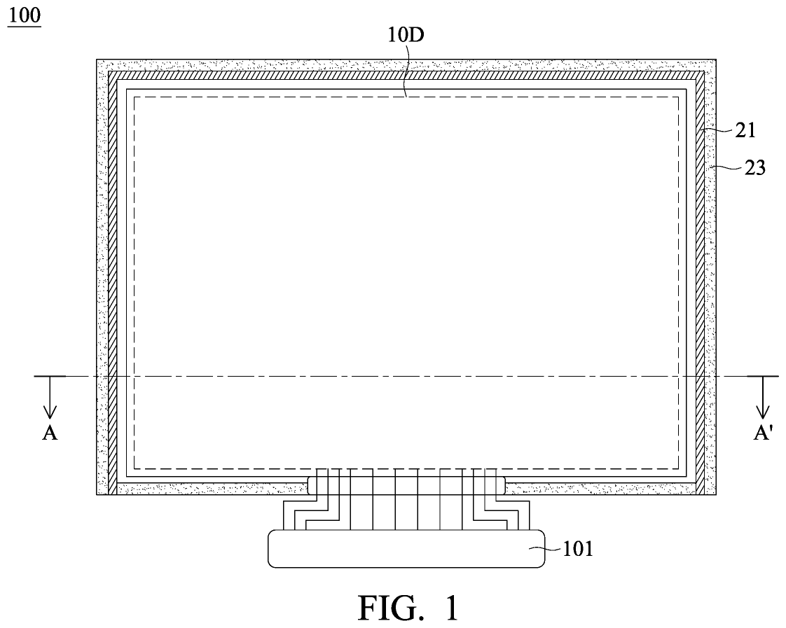

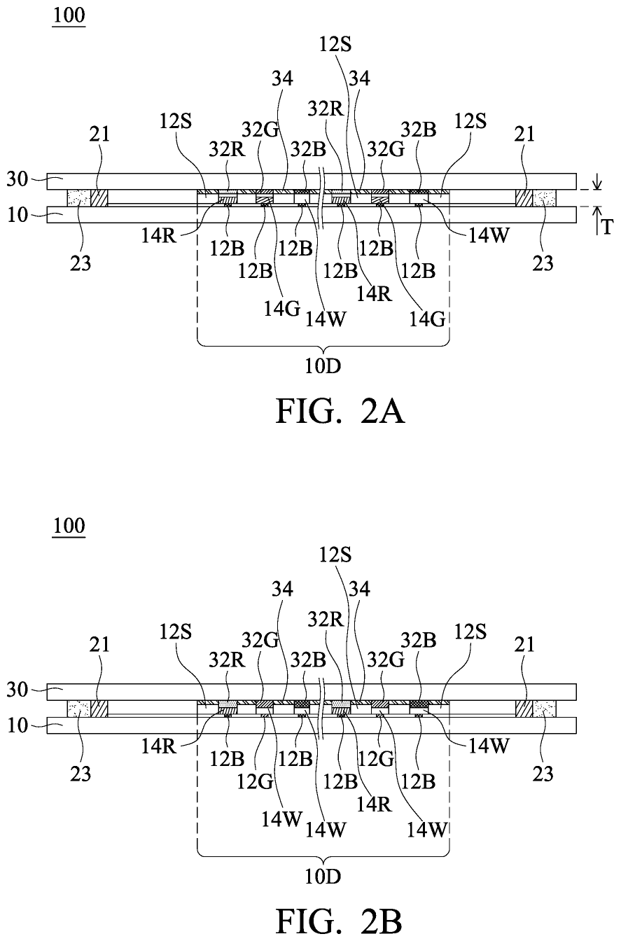

FIG. 1 is a partial top view of illustrating the micro LED display device 100 according to an embodiment of the present disclosure. FIG. 2A is a partial cross-sectional view illustrating the micro LED display device 100 along line A-A′ according to an embodiment of the present disclosure. FIG. 2B is a partial cross-sectional view illustrating the micro LED display device 100 along line A-A′ according to another embodiment of the present disclosure. It should be noted that some components have been omitted in FIG. 1, FIG. 2A and FIG. 2B for sake of brevity. Moreover, FIG. 1 also shows some circuit connection relationships of the micro LED display device 100, but does not represent all circuits of the micro LED display device 100.

Referring to FIG. 1 and FIG. 2A, the micro LED display device 100 includes a substrate 10, and the substrate 10 has a display region 10D. The substrate 10 may be, fir example, a rigid circuit substrate, which may include element semiconductors (e.g., silicon or germanium), compound semiconductors e.g., silicon carbide (SIC), gallium arsenide (GaAs), indium arsenide (InAs) or indium phosphide (InP)), alloy semiconductors (e.g., SiGe, SiGeC, GaAsP or GaInP), other suitable senmiconductors, or a combination thereof. The substrate 10 may also be a flexible circuit substrate, a semiconductor-on-insulator (SOI) substrate, or a glass substrate. Moreover, the substrate 10 may include various conductive features (e.g., conductive lines or vias). For example, the aforementioned conductive features may include aluminum (Al), copper (Cu), tungsten (W), their respective alloys, other suitable conductive materials, or a combination thereof. The substrate 10 may be joined with the external circuit substrate 101 to drive and operate the display region 10D to display images.

Referring to FIG. 2A, in some embodiments, the micro LED display device 100 includes a plurality of micro LED structures 12B disposed inside the display region 10D of the substrate 10. For example, the micro LED structure 12B is a micro blue LED chip that may emit blue light, but the present disclosure is not limited thereto. In some embodiments, the micro LED structures 12B are arranged in an array and form a plurality of pixels to display images.

For example, the micro LED structure 12B may include an N-type semiconductor layer, a light-emitting layer, and a P-type semiconductor layer, and the light-emitting layer is disposed between the N-type semiconductor layer and the P-type semiconductor layer. Moreover, the thickness of the micro LED structure 12B is, for example, not more than 10 micrometers, and the width of the micro LED structure 12B is, for example, not more than 50 micrometers. The light emitted by the micro LED structure is determined by the light-omitting layer. For example, the micro LED structure 12B may omit blue light, but the present disclosure is not limited thereto. The light-emitting layer of the micro LED structure may also emit ultraviolet light, green light, cyan light, yellow light, any other suitable color light, or a combination thereof.

The N-type semiconductor layer may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the N-type semiconductor layer may include dopants such as silicon (Si) or germanium (Ge), but the present disclosure is not limited thereto.

The light-emitting layer may include at least one undoped semiconductor layer or at least one low-doped semiconductor layer. For example, the light-emitting layer may be a quantum well (QW) layer, which may include indium gallium nitride (InₓGa₁₋ₓN) or gallium nitride (GaN), but the present disclosure is not limited thereto. Alternately, the light-emitting layer may be a multiple quantum well (MQW) layer.

The P-type semiconductor layer may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the P-type semiconductor layer may include dopants such as magnesium (Mg) or carbon (C), but the present disclosure is not limited thereto. Moreover, the N-type semiconductor layer and the P-type semiconductor layer may each be a single-layer or a multi-layer structure.

In some embodiments, the micro LED display device 100 includes a plurality of light-converting structures 14R, MG disposed on some micro LED structures 12B to convert wavelengths of lights emitted by the micro LED structures 12B. For example, the light-converting structure 14R may include red quantum dots, and the light-converting structure 14G may include green quantum dots, and the light-converting structures 14R, 14G are respectively disposed on the micro LED structures 12B that emit blue lights. In some embodiments, the micro LED display device 100 also includes a plurality of transparent structures 14W disposed on other micro LED structures 12B.

In some embodiments, the light-converting structures 14R, 14G cover the micro LED structures 12B and are in contact with the micro LED structures 12B. Specifically, the light-converting structures 14R may correspond to red sub-pixels, and the red quantum dot material of the light-converting structures 14R may emit red lights after being excited by the blue lights emitted by the micro LED structures 12B; the light-converting structures 14G may correspond to green sub-pixels, and the green quantum dot material of the light-converting structures 14G may emit green lights after being excited by the blue lights emitted by the micro LED structures 12B; the transparent structures 14W may correspond to blue sub-pixels, and the blue lights emitted by the micro LED structures 12B may penetrate the transparent structures 14W, but the present disclosure is not limited thereto. The aforementioned red sub-pixels, green sub-pixels, and blue sub-pixels may be combined into one pixel, and multiple pixels are arranged in an array in the display region 10D to display an image.

The micro LED display device 100 includes a positioning frame 21 and an isolation frame 23, the positioning frame 21 is disposed outside the display region 100, and the isolation frame 23 surrounds the positioning frame 21. Specifically, as shown in FIG. 1, the isolation frame 23 is disposed outside the positioning frame 21 and adjacent to the positioning frame 21. The positioning frame 21 and the isolation frame 23 are respectively composed of different organic rubber materials, which may include polymer materials, such as epoxy resin, acrylic resin, any other suitable material or a combination thereof, but the present disclosure is not limited thereto.

In some embodiments, the water vapor transmission rate (WVTR) of the isolation frame 23 is lower than the water vapor transmission rate of the positioning frame 21. For example, the water vapor transmission rate of the isolation frame 23 may be lower than 1%. In some embodiments, the oxygen transmission rate (OTR) of the isolation frame 23 is also lower than the oxygen transmission rate of the positioning frame 21. In other words, the isolation frame 23 has better water and oxygen resistance than the positioning frame 21.

The positioning frame 21 may be formed, for example, by ink jet printing, the isolation frame 23 may be formed, for example, by a dispensing process, and both the positioning frame 21 and the isolation frame 23 may be cured under ultraviolet light (UV) with a wavelength of 365 nm.

In some embodiments, the micro LED display device 100 includes a cover plate 30 disposed on the substrate 10 and connected to the substrate 10 by the positioning frame 21 and the isolation frame 23. For example, both the positioning frame 21 and the isolation frame 23 have a high adhesive force (e.g., greater than about 1 N/mm²). Therefore, after the hot pressing process, the cover plate 30 and the substrate 10 may be firmly connected.

As shown in FIG. 2A, in some embodiments, the thickness T of the positioning frame 21 and the isolation frame 23 is from about 15 μm to about 30 μm. Therefore, the distance between the cover plate 30 and the substrate 10 may be maintained between about 15 μm and about 30 μm.

In some embodiments, the viscosity of the positioning frame 21 is less than the viscosity of the isolation frame 23. For example, the viscosity of the positioning frame 21 may be less than about 25 cP, and the viscosity of the isolation frame 23 may be greater than about 2500 cP. As shown in FIG. 1, the top area of the positioning frame 21 is smaller than the top area of the isolation frame 23. Here, the top area of the positioning frame 21 is defined as the contact area between the positioning frame 21 and the cover 30, and the top area of the isolation frame 23 is defined as the contact area between the isolation frame 23 and the cover 30.

As shown in FIG. 1 and FIG. 2A, the positioning frame 21 and the isolation frame 23 are both outside the display region 10D of the substrate 10. That is, the positioning frame 21 and the isolation frame 23 are separated from the internal components (e.g., the micro LED structures 12B, the light-converting structures 14R 14G, the transparent structures 14W, and so on) of the display region 10D. Due to the physical characteristics of the positioning frame 21, the cover plate 30 and the substrate 10 may be aligned more accurately and maintain a uniform distance, thereby effectively improving the chromatic aberration. Since the solation frame 23 has better water and oxygen resistance, it may effectively block environmental factors such as water and oxygen from the outside of the display region 10D of the substrate 10 to protect the components inside the display region 10D.

Moreover, in some embodiments, the light transmittance of the isolation frame 23 is less than the light transmittance of the positioning frame 21. Since the isolation frame 23 surrounds the positioning frame 21, the isolation frame 23 with lower light transmittance may further prevent light leakage of the micro LED display device 100.

As shown in FIG. 2A, in some embodiments, the micro LED display device 100 includes a blocking grid 12S disposed on the micro LED structures 12B and having a plurality of recesses, the recesses correspond to and expose (at least a portion of) the micro LED structures 12B, and the light-converting structures 14R, 14G and the transparent structure 14W are disposed in the recesses. Specifically, as shown in FIG. 2A, the blocking grid 12S may he disposed between the light-converting structures 14R, the light-converting structures 14G, and the transparent structures 14W. The blocking grid 12S may include a light-absorbing insulating material or a reflective insulating material, such as a black photoresist, but the present disclosure is not limited thereto.

The blocking grid 12S may be formed by a deposition process, such as a chemical vapor deposition process, an atomic layer deposition process, a spin coating process, a similar deposition process, or a combination thereof, but the present disclosure is not limited thereto. For example, the aforementioned insulating material may be formed on the substrate 10 by a deposition process. Then, a plurality of recesses may be formed in the aforementioned insulating material by a patterning process to form the blocking grid 12S. The recesses of the blocking grid 12S may expose at least a portion of each micro LED structure 12B. Moreover, the light-converting structures 14R, the light-converting structures 14G, and the transparent structures 14W may be formed in the recesses of the blocking grid 12S, and cover and are in contact with the corresponding micro LED structures 12B, but the present disclosure is not limited thereto.

As shown in FIG. 2A. in some embodiments, the micro LED display device 100 includes a plurality of color filter structures 32R, 32G, 32B that are disposed on a side of the cover plate 30 close to the substrate 10 and correspond to the micro LED structures 12B. For example, the color filter structure 32R is a red color filter structure, which corresponds to the light-converting structure 14R (e.g., disposed on the light-converting structure 14R) and may block most of the non-red light from passing through; the color filter structure 32G is a green color filter structure, which corresponds to the light-converting structure 14G (e.g., disposed on the light-converting structure 14G) and may block most of the non-green light from passing through; the color filter structure 32B is a blue color filter structure, which corresponds to the transparent structure 14W (e.g., disposed on the transparent structure 14W) and may block most of the non-blue light from passing through. The color filter structures 32R, 32G, and 32B may further enhance the color saturation of the micro LED display device 100.

As shown in FIG. 2A, in some embodiments, the micro LED display device 100 includes a plurality of light-shielding structures 34 that are also disposed on the side of the cover plate 30 close to the substrate 10 and between the color filter structures 32R, 32G, and 32B. The light-shielding structures 34 may be used to shield the lights emitted by the micro LED structures 12B and passing through the light-converting structures 14R, the light-converting structures 14G, or the transparent structures 14W, and prevent crosstalk between them.

For example, the light-shielding structures 34 may include metal, such as copper (Cu), silver (Ag), and the like. In addition, the light-shielding structure 34 may also include a photoresist (e.g., a black photoresist or any other suitable non-transparent photoresist), an ink (e.g., black ink or any other suitable non-transparent ink), a molding compound (e.g., black molding compound or any other suitable non-transparent molding compound), a solder mask (e.g., black solder mask or any other suitable non-transparent solder mask), an epoxy resin, any other suitable material, or a combination thereof. The light-shielding structure 34 may include a light-curing material, a thermal-curing material, or a combination thereof, but the present disclosure is not limited thereto.

In some embodiments, the manufacturing method of the micro LED display device 100 includes at least the following steps. First, a substrate 10 is provided, and the substrate 10 has a display region 10D. Then, a plurality of micro LED structures 12B are formed inside the display region 10D and arranged in an array. Next, a plurality of light-converting structures 14R, 14G are formed on some micro

LED structures 12B. Then, a positioning frame 21 is formed outside the display region 10D of the substrate 10. Next, a pressing process is performed to connect the cover plate 30 to the substrate 10. Specifically, the cover plate 30 may be connected to the substrate 10 by the positioning frame 21, and the positioning frame 21 may be cured, for example, through ultraviolet light (UV). Then, the isolation frame 23 is coated between the substrate 10 and the cover plate 30 along the periphery of the positioning frame 21. Finally, a pressing process is performed again. Specifically, the isolation frame 23 may be cured, for example, through ultraviolet light (UV).

In some other embodiments, the light-converting structures 14R, 14G are disposed on the cover plate 30 and between the color filter structures 32R, 32G and the micro LED structures 12B, but the present disclosure is not limited thereto.

FIG. 2B is another partial cross-sectional view of the micro LED display device 100. The main difference from FIG. 2A is that the micro LED display device 100 also includes a plurality of micro LED structures 12G. For example, the micro LED structure 12G is a micro green LED chip that may emit green light. That is, in some embodiments, the micro LED display device 100 includes at least two different micro LED structures.

In addition, the color filter structures 32R, 32G, 32B and the light-shielding structures 34 may not be disposed on the cover plate 30. In some embodiments, the color filter structures 32R, 32G, and 32B are disposed in the recesses of the blocking grid 12S and on the light-converting structures 14R or the transparent structures 14W. The light-shielding structure 34 is disposed (or directly formed) on the blocking grid 12S. In other words, the cover plate 30 may be a transparent empty plate, so that the cover plate 30 does not require fine alignment accuracy when it is attached to the substrate 10.

As shown in FIG. 2B, the micro LED display device 100 does not include the light-converting structures 14G. In contrast, the micro LED display device 100 includes micro LED structures 12B that emit blue lights and micro LED structures 12G that emit green lights, and the transparent structures 14W are also disposed on the micro LED structures 12G. In other words, the transparent structures 14W may also correspond to green sub-pixels, and the green lights emitted by the micro LED structures 12G may penetrate the transparent structures 14W, but the present disclosure is not limited thereto. Furthermore, as shown in FIG. 2B, the color filter structure 32G is green filter structure, which corresponds to the transparent structure 14W (e.g., disposed on the transparent structure 14W) and may block most of the non-green light from passing through.

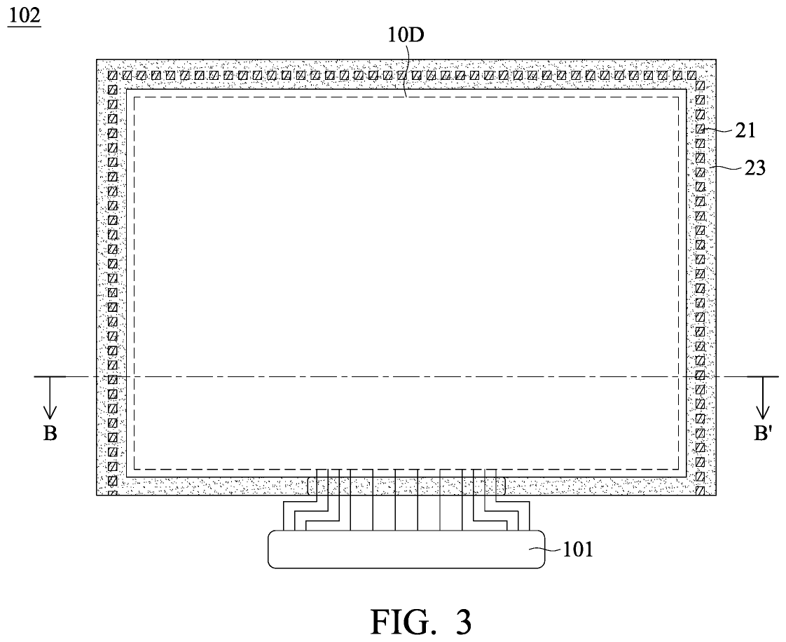

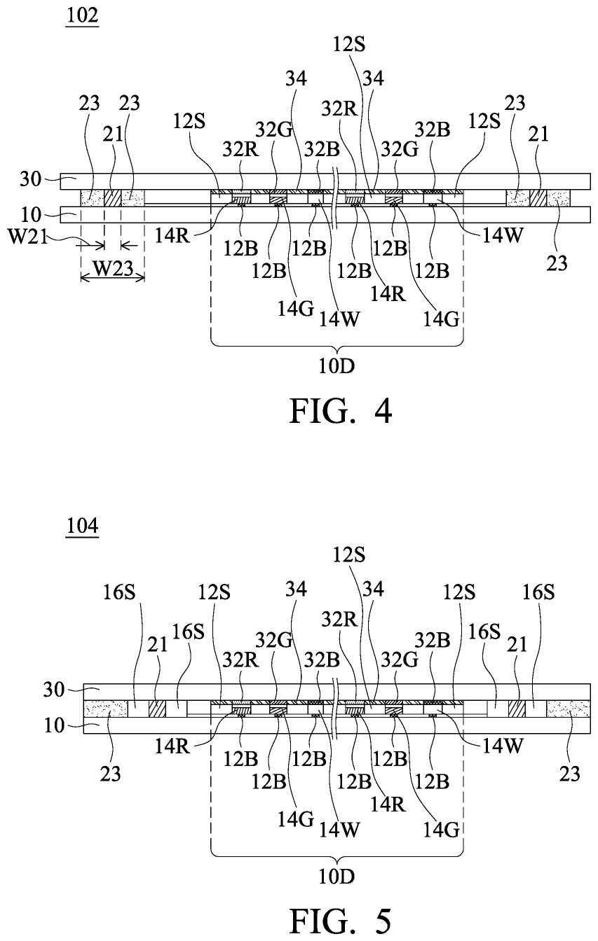

FIG. 3 is a partial top view of illustrating the micro LED display device 102 according to an embodiment of the present disclosure. FIG. 4 is a partial cross-sectional view illustrating the micro LED display device 102 along line B-B′ of FIG. 3. Similarly, some components of the micro LED display device 102 have been omitted in FIG. 3 and FIG. 4 for sake of brevity. Moreover, FIG. 3 also shows some circuit connection relationships of the micro LED display device 102, but does not represent all circuits of the micro LED display device 102.

The micro LED display device 102 has a structure similar to that of the micro LED display device 100, and the main difference lies in the structure of the positioning frame 21. As shown in FIG. 3 and FIG. 4, in some embodiments, the positioning frame 21 is formed as a discontinuous pattern. In more detail, the positioning frame 21 includes a plurality of segments, the segments are separated from each other to form the discontinuous pattern, and there is a gap between every two adjacent segments. For example, the positioning frame 21 may be formed by ink jet printing to include a plurality of segments separated from each other. In addition, during the hot pressing process, the isolation frame 23 may pass through the gaps between these segments. Therefore, as shown in FIG. 3 and FIG. 4, in some embodiments, the isolation frame 23 is simultaneously disposed inside and outside the positioning frame 21 after curing, and encloses the entire periphery of the display region 10D.

As shown in FIG. 4, in some embodiments, the width W21 of the positioning frame 21 is smaller than the width W23 of the isolation frame 23. For example, the width W21 of the positioning frame 21 may be between about 100 μm and about 1000 μm, and the width W23 of the isolation frame 23 may be between about 0.5 mm and about 8 mm. If the width W21 of the positioning frame 21 is too small, then the adhesive force is insufficient, and the cover plate 30 and the substrate 10 cannot be firmly connected. If the width W23 of the isolation frame 23 is too small, then the water and oxygen resistance is insufficient, and environmental factors such as water and oxygen cannot be blocked from the outside of the display region 10D of the substrate 10. Conversely, if the width W21 of the positioning frame 21 or the width W23 of the isolation frame 23 is too large, then the overall frame (or non-display region) of the micro LED display device 102 will he too large, and the visual and aesthetic experience for the viewer will decline.

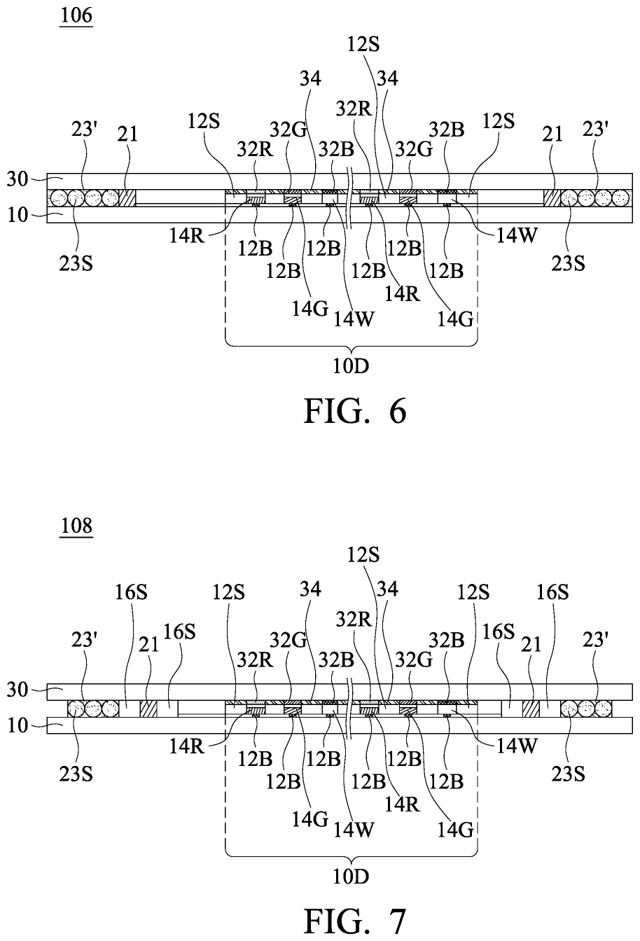

FIG. 5 is a partial cross-sectional view of illustrating the micro LED display device 104 according to another embodiment of the present disclosure. FIG. 6 is a partial cross-sectional view of illustrating the micro LED display device 106 according to another embodiment of the present disclosure. FIG. 7 is a partial cross-sectional view of illustrating the micro LED display device 108 according to another embodiment of the present disclosure. Similarly, some components of the micro LED display device 104, the micro LED display device 106, and the micro LED display device 108 have been omitted in FIG. 5 to FIG. 7 for sake of brevity. Moreover, the partial top view of the micro LED display device 104, the micro LED display device 106, and the micro LED display device 108 may be similar to the structure shown in FIG. 1 or FIG. 3, but the present disclosure is not limited thereto.

As shown in FIG. 5, in some embodiments, the micro LED display device 104 further includes a barrier structure 16S disposed outside the display region 10D of the substrate 10 and having a recess, and the positioning frame 21 is disposed in the recess. For example, the barrier structure 16S may include the same or similar materials as the blocking grid 12S. Examples of these materials are as described above and will not be repeated here.

Moreover, the barrier structure 16S may be formed on the substrate 10 by a deposition process (and a patterning process). Examples of the deposition process are described above and will not be repeated here. For example, the barrier structure 16S and the blocking grid 12S may be formed at the same time by the same manufacturing process, but the present disclosure is not limited thereto. Since the positioning frame 21 is disposed in the recess of the barrier structure 16S, the barrier structure 16S may more accurately control the position of the positioning frame 21, so that the cover plate 30 and the substrate 10 may be aligned more accurately. In addition, as shown in FIG. 5, the barrier structure 16S may block the isolation frame 23 from the outside of the positioning frame 21 to prevent the isolation frame 23 from entering the display region 10D of the substrate 10 during the pressing or thermal curing process. Therefore, the distance between the positioning frame 21 (or the isolation frame 23) and the display region 10D of the substrate 10 may be shortened, and the frame width of the micro LED display device 104 may be reduced.

As shown in FIG. 6, in some embodiments, the isolation frame 23′ of the micro LED display device 106 has a plurality of spacers 23S. Specifically, the isolation frame 23′ may have a plurality of spacers 23S, and these spacers 23S may maintain the isolation frame 23′ at a specific thickness, thereby keeping the cover plate 30 and the substrate 10 at a specific distance, such as between about 20 μm and about 30 μm.

As shown in FIG. 7, similarly, in some embodiments, the micro LED display device 108 further includes a barrier structure 16S disposed outside the display region 10D of the substrate 10 and having a recess, and the positioning frame 21 is disposed in the recess, thereby more accurately controlling the position of the positioning frame 21, so that the cover plate 30 and the substrate 10 may be aligned more accurately. Moreover, the isolation frame 23′ of the micro LED display device 108 has a plurality of spacers 23S. Specifically, the isolation frame 23′ may have a plurality of spacers 23S to maintain the isolation frame 23′ at a specific thickness, thereby keeping the cover plate 30 and the substrate 10 at a specific distance.

In summary, in the embodiments of the present disclosure, the micro LED display device includes a positioning frame and an isolation frame, and the water vapor transmission rate of the isolation frame is lower than the water vapor transmission rate of the positioning frame. The positioning frame may provide more accurate alignment of the two substrates in the micro LED display device, thereby effectively improving the chromatic aberration. Moreover, the isolation frame may effectively block environmental factors such as water and oxygen to protect the components inside the display region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description provided herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A micro LED display device, comprising:
a substrate having a display region;
a plurality of micro LED structures disposed inside the display region and arranged in an array;
a plurality of light-converting structures disposed on a portion of the micro LED structures to convert wavelengths of lights emitted by the portion of the micro LED structures;
a positioning frame disposed outside the display region;
an isolation frame surrounding the positioning frame, wherein a water vapor transmission rate of the isolation frame is lower than a water vapor transmission rate of the positioning frame; and
a cover plate disposed on the substrate and connected to the substrate by the positioning frame and the isolation frame.

2. The micro LED display device as claimed in claim 1, wherein the positioning frame and the isolation frame are respectively composed of different organic rubber materials.

3. The micro LED display device as claimed in claim 2, wherein an oxygen transmission rate of the isolation frame is lower than an oxygen transmission rate of the positioning frame.

4. The micro LED display device as claimed in claim 2, wherein a viscosity of the positioning frame is less than a viscosity of the isolation frame.

5. The micro LED display device as claimed in claim 2, wherein a light transmittance of the isolation frame is less than a light transmittance of the positioning frame.

6. The micro LED display device as claimed in claim 2, wherein a top area of the positioning frame is smaller than a top area of the isolation frame.

7. The micro LED display device as claimed in claim 2, wherein the isolation frame is simultaneously disposed inside and outside the positioning frame.

8. The micro LED display device as claimed in claim 2, wherein the positioning frame is formed as a discontinuous pattern.

9. The micro LED display device as claimed in claim 8, wherein the positioning frame comprises a plurality of segments, the segments are separated from each other to form the discontinuous pattern, and there is a gap between every two adjacent segments.

10. The micro LED display device as claimed in claim 1, further comprising:
a barrier structure disposed outside the display region and having a recess, wherein the positioning frame is disposed in the recess.

11. The micro LED display device as claimed in claim 1, wherein the isolation frame has a plurality of spacers.

12. The micro LED display device as claimed in claim 1, wherein a width of the positioning frame is smaller than a width of the isolation frame.

13. The micro LED display device as claimed in claim 1, further comprising:
a blocking grid disposed on the micro LED structures and having a plurality of recesses, the recesses correspond to and expose the micro LED structures, and the light-converting structures are disposed in the recesses.

14. The micro LED display device as claimed in claim 13, further comprising:
a plurality of color filter structures disposed in the recesses of the blocking grid and on the light-converting structures.

15. The micro LED display device as claimed in claim 1, wherein the light-converting structures cover the micro LED structures and are in contact with the micro LED structures.

16. The micro LED display device as claimed in claim 1, further comprising:
a plurality of color filter structures disposed on a side of the cover plate close to the substrate and corresponding to the micro LED structures.

17. The micro LED display device as claimed in claim 16, further comprising:
a plurality of light-shielding structures disposed between the color filter structures.
